(19) United States
(12) Patent Application Publication
(10) Pub. No.: US 2025/0029955 A1
(43) Pub. Date: Jan. 23, 2025

(54) SEMICONDUCTOR PACKAGE HAVING AN INORGANIC LAYER ON A MOLD LAYER AND METHOD OF FABRICATING THE SAME

(71) Applicant: SAMSUNG ELECTRONICS CO., LTD., SUWON-SI (KR)

(72) Inventors: Jihoon JUNG, Suwon-si (KR); UN-BYOUNG KANG, Suwon-si (KR); YEONGKWON KO, Suwon-si (KR); KUYOUNG KIM, Suwon-si (KR)

(21) Appl. No.: 18/616,418

(22) Filed: Mar. 26, 2024

(30) Foreign Application Priority Data
Jul. 19, 2023 (KR) 10-2023-0094080
Sep. 13, 2023 (KR) 10-2023-0121516

(51) Int. Cl. H01L 25/065; H01L 23/00; H01L 23/29; H01L 23/31; H01L 23/48; H10B 80/00

(52) U.S. Cl. CPC H01L 25/0657; H01L 23/291; H01L 23/3192; H01L 23/481; H01L 24/16; H01L 24/32; H01L 24/73; H01L 25/0652; H10B 80/00; H01L 2224/16145; H01L 2224/16227; H01L 2224/32145; H01L 2224/32225; H01L 2224/73204

(57) ABSTRACT

A semiconductor package includes: a buffer die; a plurality of memory dies stacked on the buffer die; a mold layer covering a portion of a top surface of the buffer die and lateral surfaces of the plurality of memory dies; and an inorganic layer disposed on the mold layer, wherein the inorganic layer covers at least a portion of the lateral surface of an uppermost memory die of the plurality of memory dies, wherein a top surface of the inorganic layer is substantially coplanar with a top surface of the uppermost memory die of the plurality of memory dies, and wherein the inorganic layer includes oxide or nitride.

### CROSS-REFERENCE TO RELATED APPLICATIONS

This U.S. nonprovisional application claims priority under 35 U.S.C. § 119 to Korean Patent Applications No. 10-2023-0094080 filed on Jul. 19, 2023 and No. 10-2023-0121516 filed on Sep. 13, 2023 in the Korean Intellectual Property Office, the disclosures of which are incorporated by reference herein in their entireties.

### TECHNICAL FIELD

Embodiments of the present inventive concept relate to a semiconductor package and a method of fabricating the same, and more particularly, to a semiconductor package having an inorganic layer on a mold layer and a method of fabricating the same.

### Discussion of the Related Art

A semiconductor package is provided to implement an integrated circuit chip to be provided in electronic products. A semiconductor package is typically configured such that a semiconductor chip is mounted on a printed circuit board (PCB) and bonding wires or bumps are used to electrically connect the semiconductor chip to the printed circuit board. With the development of electronic industry, semiconductor packages have been under development to have increased reliability and durability.

### SUMMARY

According to embodiments of the present inventive concept, a semiconductor package includes: a buffer die; a plurality of memory dies stacked on the buffer die; a mold layer covering a portion of a top surface of the buffer die and lateral surfaces of the plurality of memory dies; and an inorganic layer disposed on the mold layer, wherein the inorganic layer covers at least a portion of the lateral surface of an uppermost memory die of the plurality of memory dies, wherein a top surface of the inorganic layer is substantially coplanar with a top surface of the uppermost memory die of the plurality of memory dies, and wherein the inorganic layer includes oxide or nitride.

According to embodiments of the present inventive concept, a semiconductor package includes: a buffer die; a plurality of memory dies stacked on the buffer die; a mold layer that covers a portion of a top surface of the buffer die and lateral surfaces of the plurality of memory dies; and an inorganic layer disposed on the mold layer, wherein the buffer die includes: a first through via; and a plurality of external connection members disposed on a lower portion of the buffer die, wherein the memory dies include first to fourth memory dies that are sequentially stacked on the buffer die, wherein each of the first to third memory dies includes a second through via, wherein the inorganic layer covers at least a portion of the lateral surface of the fourth memory die, wherein a top surface of the inorganic layer and a top surface of the fourth memory die are substantially coplanar with each other, wherein a thermal conductivity of the inorganic layer is greater than a thermal conductivity of the mold layer, wherein a stiffness of the inorganic layer is greater than a stiffness of the mold layer, wherein a lateral surface of the inorganic layer and a lateral surface of the mold layer are vertically aligned with each other, wherein a thickness of the inorganic layer is in a range of about 2 μm to about 10 μm, and wherein the inorganic layer includes SiO₂.

According to embodiments of the present inventive concept, a semiconductor package includes: a package substrate; an interposer substrate disposed on the package substrate; a first semiconductor chip, a second semiconductor chip, and a third semiconductor chip that are disposed on the interposer substrate; a first mold layer that covers a portion of the interposer substrate and the first, second, and third semiconductor chips; and an inorganic layer disposed on the first mold layer, wherein each of the first and third semiconductor chips includes: a buffer die; a plurality of memory dies stacked on the buffer die; and a second mold layer that covers the buffer die and the memory dies, wherein a top surface of the inorganic layer is substantially coplanar with a top surface of each of the first, second, and third semiconductor chips, wherein the inorganic layer includes oxide or nitride, and wherein a thermal conductivity of the inorganic layer is greater than a thermal conductivity of each of the first and second mold layers.

According to embodiments of the present inventive concept, a method of fabricating a semiconductor package includes: preparing a buffer die wafer; bonding a carrier substrate to a bottom surface of the buffer die wafer through an adhesive member; providing a plurality of memory dies to the buffer die wafer; forming a mold layer that covers the plurality of memory dies and the buffer die wafer; performing a grinding process on the mold layer to expose a top surface of an uppermost memory die of the plurality of memory dies; etching the mold layer such that a top surface of the mold layer is lower than the top surface of the uppermost memory die of the plurality of memory dies; performing a deposition process to form an inorganic layer on the mold layer and the plurality of memory dies; performing a grinding process on the inorganic layer such that a top surface of the inorganic layer is substantially coplanar with the top surface of the uppermost memory die of the plurality of memory dies; performing an oxygen plasma process on the inorganic layer to cause the inorganic layer to have a hydrophilic surface; attaching the mold layer, the inorganic layer, and the top surface of the uppermost memory die of the plurality of memory dies to dicing tape; separating the carrier substrate and the adhesive member from the buffer die wafer; and performing a dicing process to cut the inorganic layer, the mold layer, and the buffer die wafer.

### BRIEF DESCRIPTION OF DRAWINGS

FIG. 1A is a plan view illustrating a semiconductor package according to embodiments of the present inventive concept.

FIG. 1B is a cross-sectional view taken along line A-A′ of FIG. 1A.

FIG. 2 is an enlarged view illustrating section P1 of FIG. 1B.

FIG. 3 is a perspective view illustrating a semiconductor package of FIG. 1B.

FIGS. 4A, 4B, 4C, 4D, 4E, 4F, 4G, 4H and 4I are cross-sectional views illustrating a method of fabricating a semiconductor package of FIG. 1B.

FIG. 5 is an enlarged view illustrating section P2 of FIG. 4G.

FIG. 6 is a cross-sectional view taken along line A-A′ of FIG. 1A.

FIG. 7 is a plan view illustrating a semiconductor package according to embodiments of the present inventive concept.

### DETAILED DESCRIPTION OF EMBODIMENTS

Embodiments of the present inventive concept will now be described in detail with reference to the accompanying drawings, in which embodiments of the present inventive concept are shown.

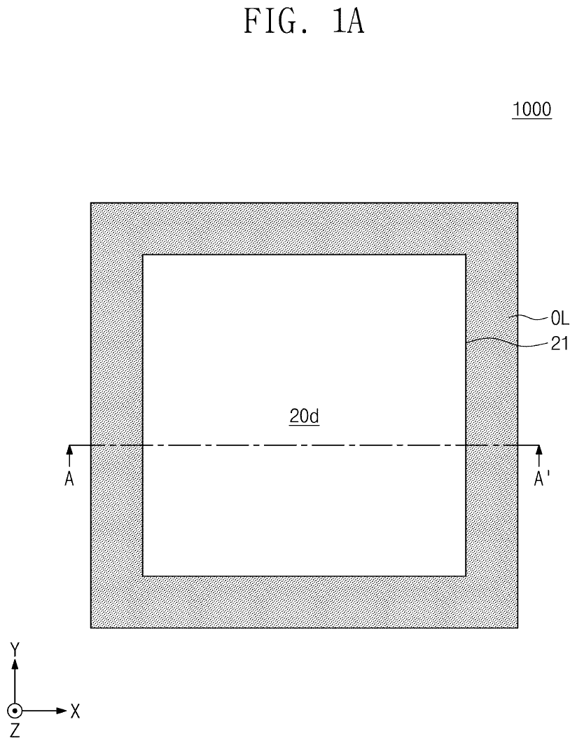

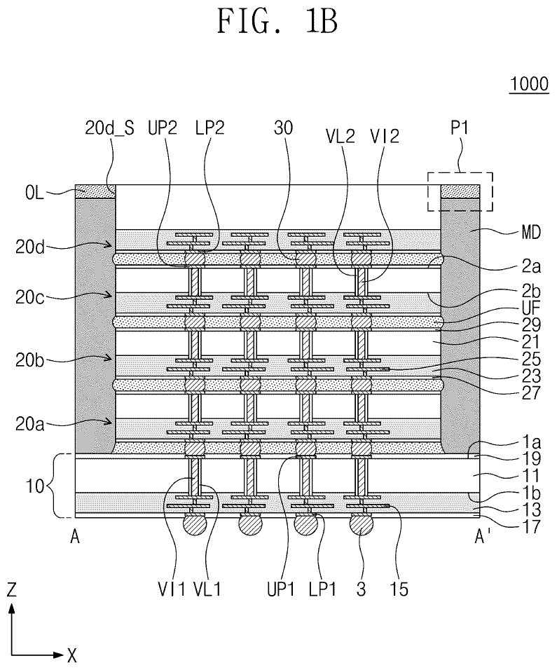

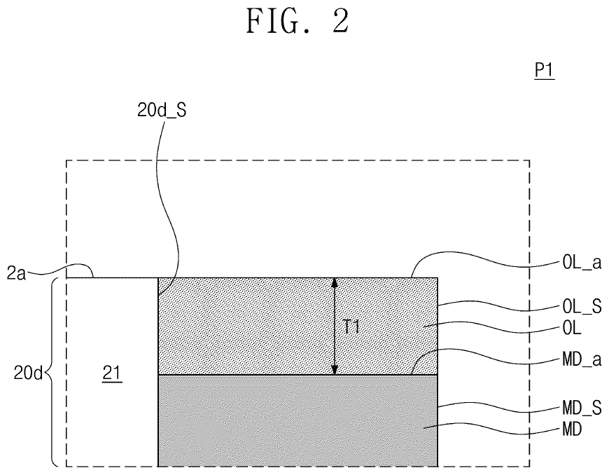

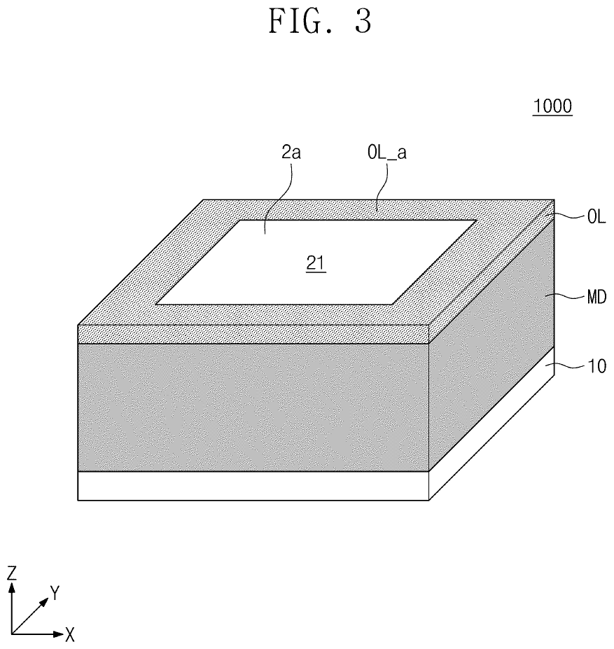

FIG. 1A is a plan view illustrating a semiconductor package according to embodiments of the present inventive concept. FIG. 1B is a cross-sectional view taken along line A-A′ of FIG. 1A. FIG. 2 is an enlarged view illustrating section P1 of FIG. 1B. FIG. 3 is a perspective view illustrating a semiconductor package of FIG. 1B.

Referring to FIGS. 1A and 1B, a semiconductor package 1000 according to embodiments of the present inventive concept may include a buffer die 10, first to fourth memory dies 20a to 20d, a mold layer MD, and an inorganic layer OL. The semiconductor package 1000 may have a high bandwidth memory (HBM) chip structure. The term “die” may be called “chip.”

The buffer die 10 may be, for example, a logic circuit chip. The buffer die 10 may serve as an interface circuit between the memory dies 20a to 20d and an external controller. The buffer die 10 may receive commands, data, and signals transmitted from the external controller, and may transfer the received commands, data, and signals to the memory dies 20a to 20d. In addition, the buffer die 10 may be an interposer die that does not include a transistor.

The first to fourth memory dies 20a to 20d may be sequentially stacked on the buffer die 10. The first to fourth memory dies 20a to 20d may be the same memory chip; however, the present inventive concept is not limited thereto. The memory chip may be, for example, dynamic random access memory (DRAM), NAND Flash, static random access memory (SRAM), magnetic random access memory (MRAM), phase change random access memory (PRAM), or resistive random access memory (RRAM). A width of the buffer die 10 may be greater than those of the first to fourth memory dies 20a to 20d. The present embodiment discloses a structure in which one logic chip and four memory chips are stacked on each other, but the stacking number of the logic chip and the memory chips may be variously changed without being limited thereto. For example, eight or more memory chips may be stacked.

The buffer die 10 may include a first substrate 11 and a first interlayer dielectric layer 13. The first substrate 11 may have a first top surface 1a and a first bottom surface 1b that are opposite to each other. Transistors and first wiring lines 15 may be provided on the first bottom surface 1b. The first interlayer dielectric layer 13 may cover the first bottom surface 1b of the first substrate 11. A first passivation layer 17 may cover a bottom surface of the first interlayer dielectric layer 13. A second passivation layer 19 may cover the first top surface 1a of the first substrate 11.

Each of the first, second, third, and fourth memory dies 20a, 20b, 20c, and 20d may include a second substrate 21 and a second interlayer dielectric layer 23. The second substrate 21 may have a second top surface 2a and a second bottom surface 2b that are opposite to each other. Transistors and second wiring lines 25 may be provided on the second bottom surface 2b. The second interlayer dielectric layer 23 may cover the second bottom surface 2b of the second substrate 21. A third passivation layer 27 may cover a bottom surface of the second interlayer dielectric layer 23. A fourth passivation layer 29 may cover the second top surface 2a of the second substrate 21. The fourth memory die 20d might not include the fourth passivation layer 29.

The substrates 11 and 21 may be a wafer-level semiconductor substrate formed of a semiconductor such as silicon (Si). For example, each of the substrates 11 and 21 may be a monocrystalline silicon substrate or a silicon-on-insulator (SOI) substrate. For example, the interlayer dielectric layers 13 and 23 may be a single layer structure or a multiple layer structure formed of at least one of silicon oxide layer, a silicon nitride layer, a silicon oxynitride layer, and/or a porous dielectric layer. For example, the wiring lines 15 and 25 may be a single-layered or multi-layered structure including at least one of copper, aluminum, tungsten, titanium, titanium nitride, tantalum, tantalum nitride, ruthenium, and/or iridium. For example, the passivation layers 17, 19, 27, and 29 may include at least one of silicon oxide, silicon nitride, and/or silicon carbonitride.

The buffer die 10 may include a first through via VI1. Each of the first, second, and third memory dies 20a, 20b, and 20c may include a second through via VI2. The fourth memory die 20d might not include the second through via VI2. The through vias VI1 and VI2 may penetrate the substrates 11 and 21 of the buffer die 10, the first memory die 20a, the second memory die 20b, and the third memory die 320c to reside on central portions of corresponding dies 10, 20a, 20b, and 20c. For example, the first through via VI1 may penetrate the first substrate 11, and the second through via VI2 may penetrate the second substrate 21. The wiring lines 15 and 25 may be connected to the through vias VI1 and VI2 that penetrate corresponding dies 10, 20a, 20b, and 20c. Through dielectric layers VL1 and VL2 may be correspondingly interposed between the through vias VI1 and VI2 and the substrates 11 and 21. The through vias VI1 and VI2 may include metal, such as copper, aluminum, or tungsten. For example, the through dielectric layers VL1 and VL2 may have a single-layered or multi-layered structure formed of at least one of silicon oxide, silicon nitride, and silicon oxynitride. The through dielectric layers VL1 and VL2 may include an air gap.

The buffer die 10 may be provided with first upper conductive pads UP1 on a top surface thereof. The first upper conductive pads UP1 may be correspondingly connected to the first through vias VI1. The buffer die 10 may be provided with first lower conductive pads LP1 on a bottom surface thereof. The first lower conductive pads LP1 may be coupled to corresponding first wiring lines 15 and may be electrically connected to corresponding first through vias VI1. The first lower conductive pads LP1 may be bonded with external connection members 3. The external connection members 3 may include at least one of, for example, copper bumps, copper pillars, and/or solder balls.

Each of the first to third memory dies 20a to 20c may be provided with second upper conductive pads UP2 on a top surface thereof. The fourth memory die 20d might not include the second upper conductive pads UP2. The second upper conductive pads UP2 may be correspondingly connected to the second through vias VI2. Each of the first to fourth memory dies 20a to 20d may be provided with second lower conductive pads LP2 on a bottom surface thereof. The second lower conductive pads LP2 may be coupled to corresponding second wiring lines 25 and may be electrically connected to corresponding second through vias VI2. The upper conductive pads UP1 and UP2 and the lower conductive pads LP1 and LP2 may include at least one of, for example, copper (Cu), gold (Au), nickel (Ni), tin (Sn), silver (Ag), tungsten (W), and/or aluminum (Al).

Internal connection members 30 may be correspondingly disposed between the buffer die 10 and the first memory die 20a and between the first to fourth memory dies 20a to 20d. The inner connection members 30 may electrically connect the first upper conductive pads UP1 of the buffer die 10 to the second lower conductive pads LP2 of the first memory die 20a. In addition, the internal connection members 30 may correspondingly electrically connect the second upper conductive pads UP2 and the second lower conductive pads LP2 of the first to fourth memory dies 20a to 20d to each other. The internal connection members 30 may include, for example, solder balls or conductive bumps.

Underfill layers UF may be provided to fill spaces between the buffer die 10 and the first memory die 20a and between the first to fourth memory dies 20a to 20d. The underfill layer UF may be formed by dispensing and curing processes. The underfill layer UF may include, for example, an epoxy resin. The underfill layer UF may protect the internal connection members 30.

The mold layer MD may cover the top surface of the buffer die 10 and lateral surfaces of the first to fourth memory dies 20a to 20d. For example, the mold layer MD may cover portions of the top surface of the buffer die 10. A top surface MD_a of the mold layer MD may be lower than the second top surface 2a of the fourth memory die 20d. The mold layer MD may cover at least a portion of a lateral surface 20d_S of the fourth memory die 20d. For example, the second top surface 2a of the fourth memory die 20d may be located higher than the top surface MD_a of the mold layer MD. The mold layer MD may include, for example, a dielectric resin, such as an epoxy molding compound (EMC). The mold layer MD may further include fillers, and the fillers may be dispersed in the dielectric resin.

The inorganic layer OL may be disposed on the mold layer MD. Referring to FIG. 2, the inorganic layer OL may cover the top surface MD_a of the mold layer MD and at least a portion of the lateral surface 20d_S of the fourth memory die 20d. The inorganic layer OL may have a thickness Tl of about 2 μm to about 10 μm. The inorganic layer OL may have a substantially flat top surface OL_a. The top surface OL_a of the inorganic layer OL may be substantially coplanar with the second top surface 2a of the fourth memory die 20d. A lateral surface OL_S of the inorganic layer OL may be vertically aligned with a lateral surface MD_S of the mold layer MD. The inorganic layer OL may include, for example, oxide or nitride. For example, the inorganic layer OL may include at least one of silicon oxide (SiO₂) and/or silicon nitride (SiN).

Referring to FIGS. 2 and 3, there may be exposed a top surface of an uppermost one of the stacked memory dies 20a to 20d and a top surface of the inorganic layer OL. In embodiments of the present inventive concept, there may be exposed the second top surface 2a of the second substrate 21 that is included in the fourth memory die 20d. The inorganic layer OL may have a thermal conductivity greater than that of the mold layer MD. As the mold layer MD is provided thereon with the inorganic layer OL having a high thermal conductivity, heat generated from the buffer die 10 and the first to fourth memory dies 20a to 20d may be effectively discharged. The semiconductor package 1000 may thus have an increased heat resistance. The inorganic layer OL may have a stiffness greater than that of the mold layer MD. As the mold layer MD is provided thereon with the inorganic layer OL having a high stiffness, the semiconductor package 1000 may be protected against external impact. As the inorganic layer OL is formed to adjust its thickness, warpage of the semiconductor package 1000 may be controlled at a top surface of the semiconductor package 1000. The semiconductor package 1000 may thus have increased durability.

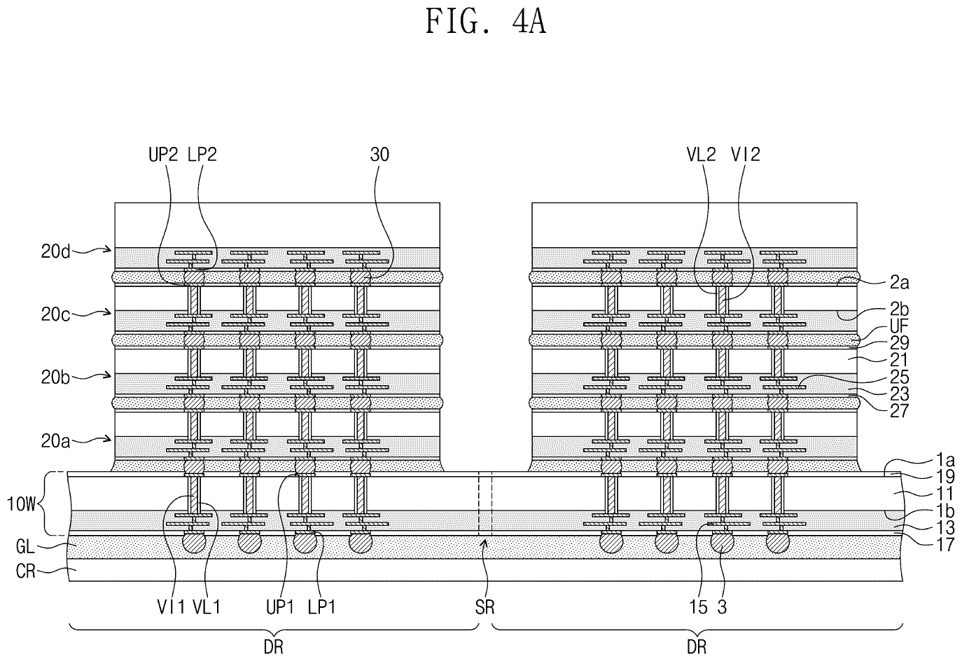

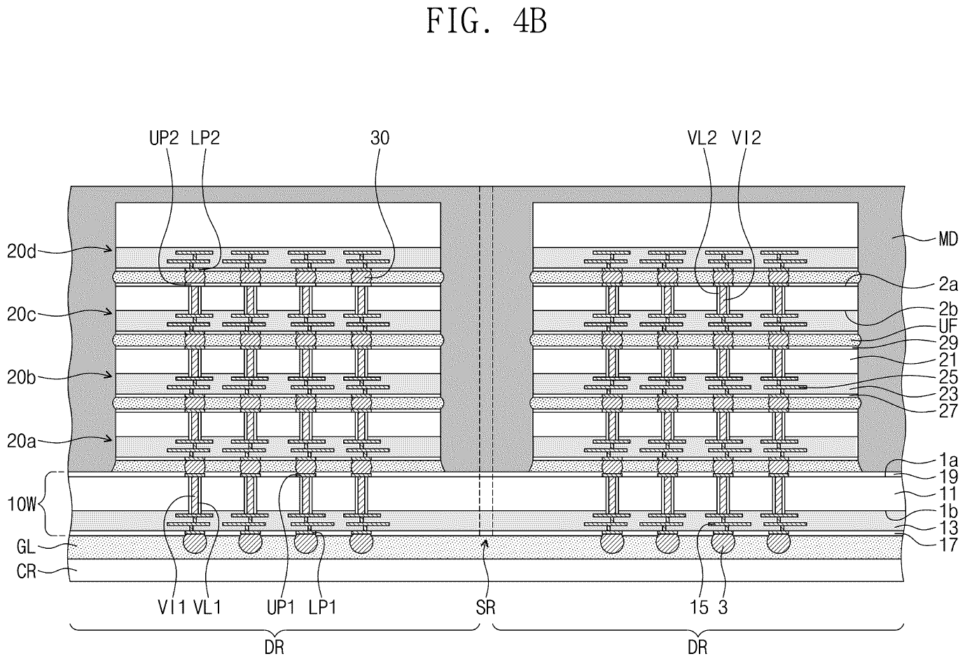

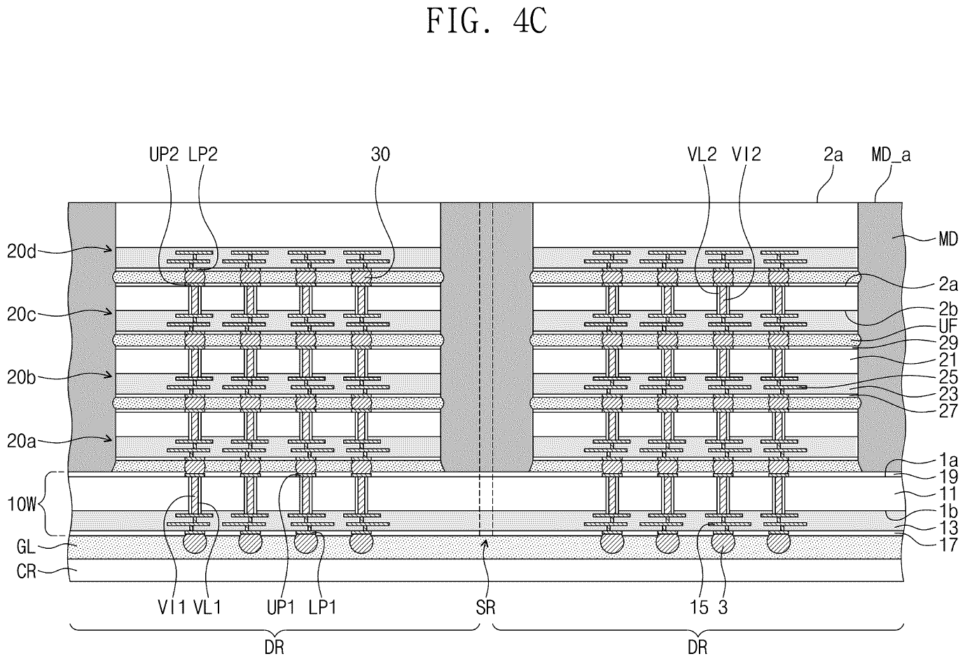

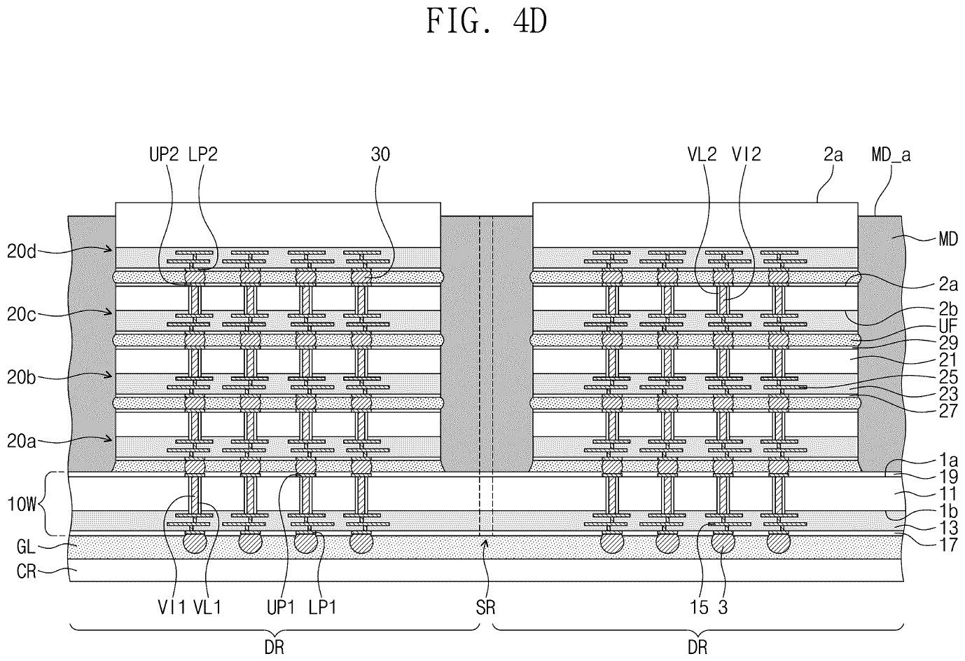

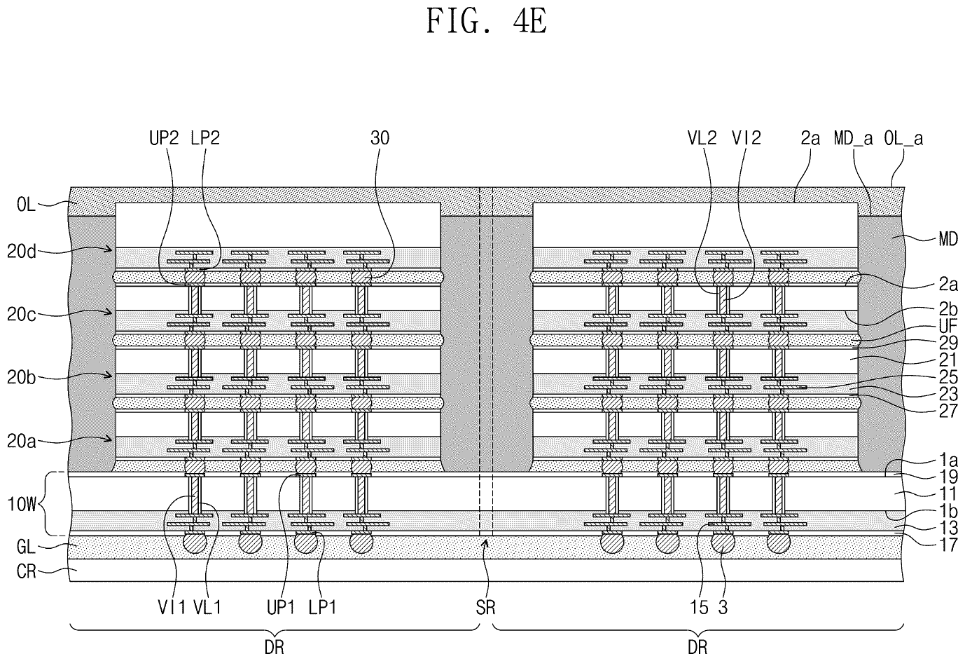

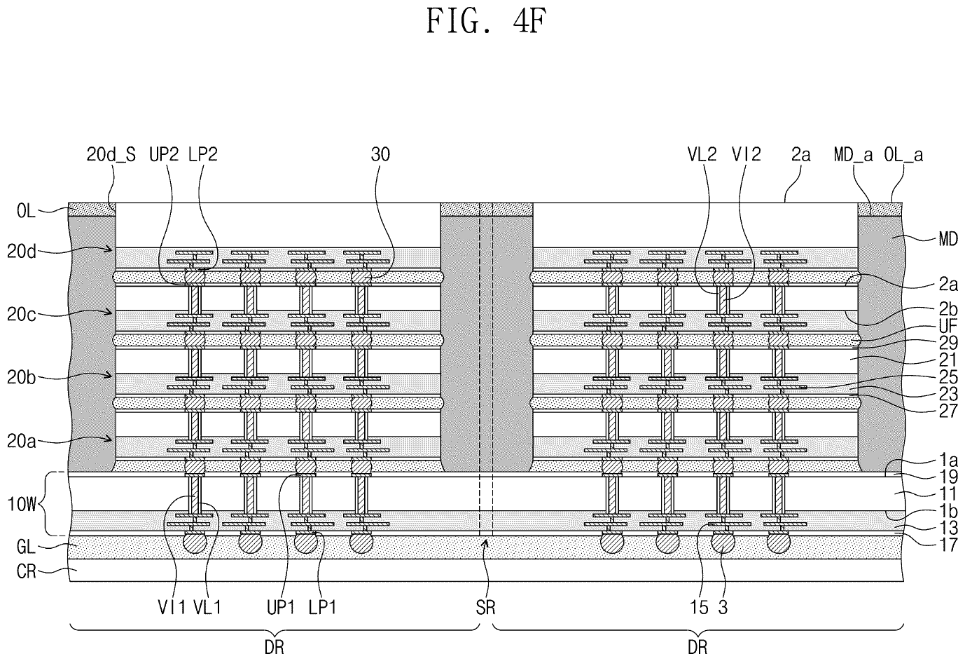

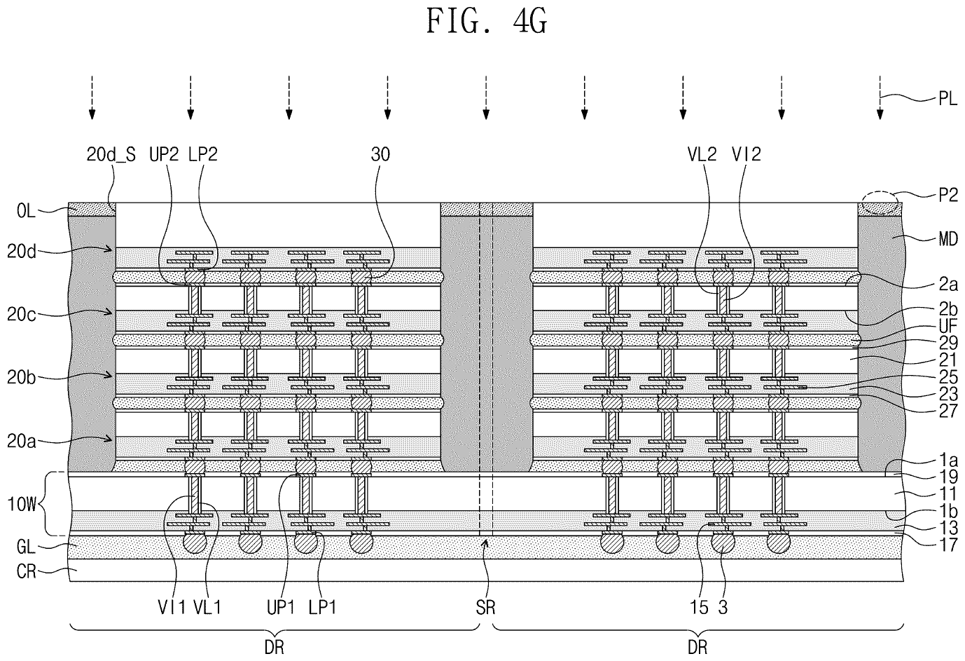

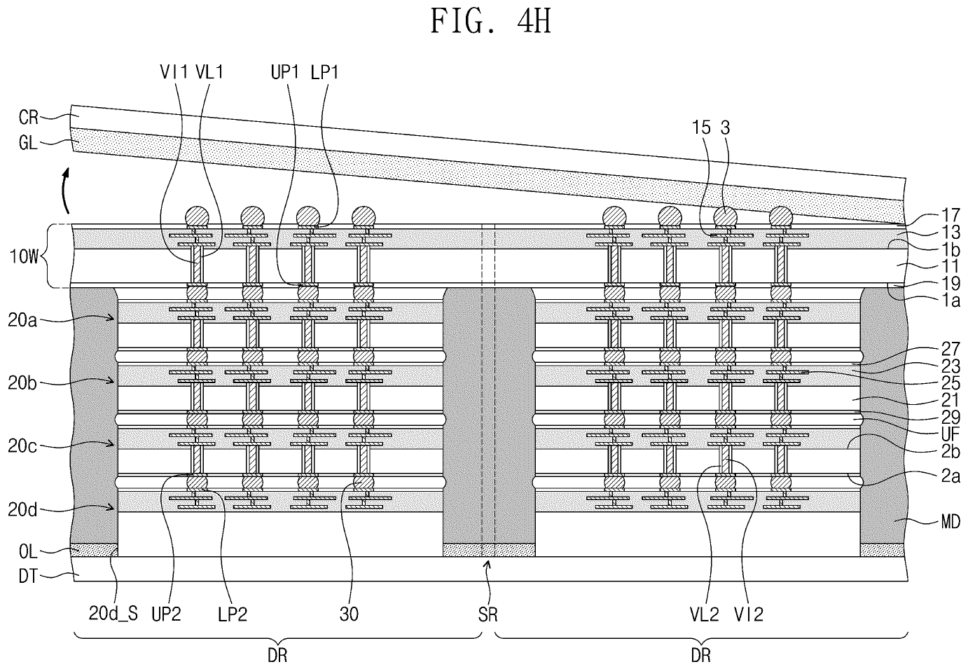

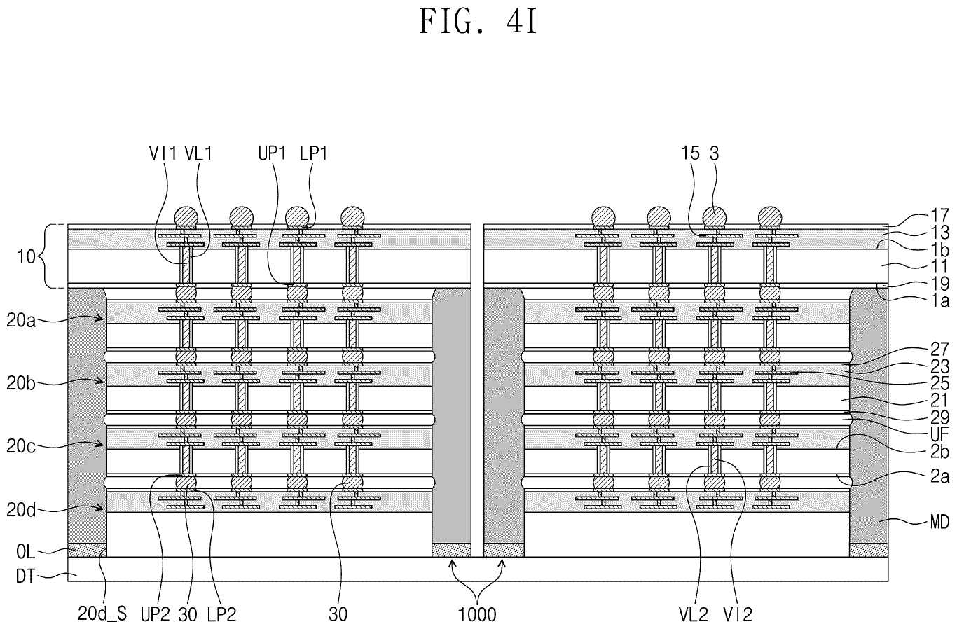

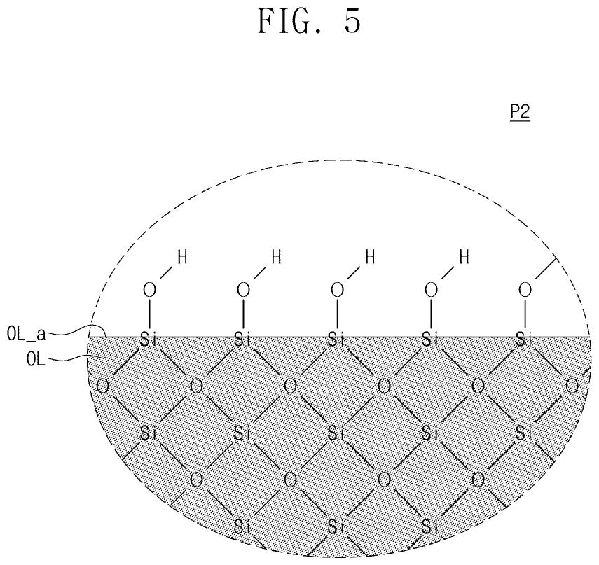

FIGS. 4A to 4I are cross-sectional views illustrating a method of fabricating a semiconductor package of FIG. 1B. FIG. 5 is an enlarged view illustrating section P2 of FIG. 4G. Like reference numerals may refer to like elements, and thus, a duplicate description may be omitted or briefly discussed below.

Referring to FIG. 4A, a buffer die wafer 10 W may be prepared. The buffer die wafer 10 W may have a plurality of chip regions DR and a separation region SR disposed between the chip regions DR. The chip regions DR of the buffer die wafer 10 W may each have a structure of the buffer die 10 discussed with reference to FIG. 1B. The separation region SR may be a scribe lane region. The buffer die wafer 10 W may include a first substrate 11. The first substrate 11 may have a first top surface 1a and a first bottom surface 1b that are opposite to each other. Transistors and a first interlayer dielectric layer 13 may be formed on the first bottom surface 1b. The first interlayer dielectric layer 13 and the first substrate 11 may be etched to form a through hole, and a first through dielectric layer VL1 and a first through via VI1 may be formed in the through hole. First wiring lines 15 may be formed in the first interlayer dielectric layer 13, and a first passivation layer 17 and first lower conductive pads LP1 may be formed on the first interlayer dielectric layer 13. External connection members 3 may be bonded to the first lower conductive pads LP1.

The buffer die wafer 10 W may be attached through a carrier adhesive layer GL to a carrier substrate CR. The carrier substrate CR may be a dielectric substrate including, for example, glass or polymer or may be a conductive substrate including metal. The carrier adhesive layer GL may include one or more of, for example, an adhesive resin, a thermosetting resin, a thermoplastic resin, and/or a photo-curable resin. The first top surface 1a of the first substrate 11 may undergo a back-grinding process to remove a portion of the first substrate 11 and to expose the first through dielectric layer VL1. A second passivation layer 19 may be formed on the first top surface 1a of the first substrate 11, and a chemical mechanical polishing (CMP) process or an etch-back process may be employed to remove a portion of the first through dielectric layer VL1 and to expose the first through via VI1. First upper conductive pads UP1 may be formed in or on the second passivation layer 19.

First to fourth memory dies 20a to 20d may be prepared. Each of the first to fourth memory dies 20a to 20d may be formed to include a second substrate 21, transistors, second wiring lines 25, a second interlayer dielectric layer 23, a second through via VI2, a second through dielectric layer VL2, second upper conductive pads UP2, second lower conductive pads LP2, and third and fourth passivation layers 27 and 29 that are formed by methods discussed in FIG. 4A. Afterwards, a sawing process may be performed to allow the first to fourth memory dies 20a to 20d to have substantially the same width.

The first to fourth memory dies 20a to 20d may be flip-chip bonded to the buffer die wafer 10 W. The first memory die 20a may be positioned on the buffer die wafer 10 W such that internal connection members 30 overlap the first upper conductive pads UP1. A thermal compression process may be performed to bond the first memory die 20a to the buffer die wafer 10 W. Likewise, the second to fourth memory dies 20b to 20d may be sequentially stacked on the first memory die 20a and thermal compression processes may be sequentially performed. In addition, the first to fourth memory dies 20a to 20d may be sequentially stacked on each chip region DR of the buffer die wafer 10 W and then one thermal compression process may be performed to bond the memory dies 20a and 20d and the buffer die wafer 10 W to each other. Dispensing and curing processes may be performed to form underfill layers UF in spaces between the buffer die wafer 10 W and the first memory die 20a and between the first to fourth memory dies 20a to 20d.

Referring to FIG. 4B, a molding process may be performed to form a mold layer MD that covers the first to fourth memory dies 20a to 20d and a top surface of the buffer die wafer 10 W.

Referring to FIG. 4C, a grinding process may be performed to remove a portion of the mold layer MD to expose a second top surface 2a of the fourth memory die 20d. In this step, the mold layer MD may be removed to cause the second top surface 2a of the fourth memory die 20d to be substantially coplanar with a top surface MD_a of the mold layer MD.

Referring to FIG. 4D, an etching process may be performed to selectively remove a portion of the mold layer MD to cause the top surface MD_a of the mold layer MD to be lower than the second top surface 2a of the fourth memory die 20d. In consideration of surface uniformity of the mold layer MD, a portion of the mold layer MD may be removed such that the top surface MD_a of the mold layer MD may be at least about 2 μm lower than the second top surface 2a of the fourth memory die 20d. When the top surface MD_a of the mold layer MD is removed by more than about 10 μm, no fillers may be removed from the mold layer MD and thus impurities may be formed. To prevent this problem, the top surface MD_a of the mold layer MD may be removed as much as a thickness of about 2 μm to about 10 μm. The etching process may include a dry etching process, such as plasma etching, sputtering, or reactive ion etching (RIE).

Referring to FIG. 4E, a deposition process may be performed to form an inorganic layer OL on the mold layer MD and the fourth memory die 20d. The inorganic layer OL may be formed to cover the top surface MD_a of the mold layer MD, the second top surface 2a of the fourth memory die 20d, and at least a portion of a lateral surface 20d_S of the fourth memory die 20d. The deposition process may include a low-temperature deposition process, such as plasma enhanced chemical vapor deposition (PECVD). The PECVD may be executed at a temperature of, for example, about 150° C. to about 400° C. In the present embodiment, the inorganic layer OL may be deposited by the PECVD process at a low temperature of about 150° C. to about 200° C. Therefore, a semiconductor package (see 1000 of FIG. 1B) may be prevented from warpage which may occur when the inorganic layer OL is deposited on the mold layer MD at a high temperature equal to or greater than about 200° C. The embodiments of the present inventive concept, however, are not limited thereto, and the inorganic layer OL may be formed by various deposition processes other than the PECVD process.

As there occurs a total thickness variation of the inorganic layer OL when it is formed, the inorganic layer OL may be formed to have a thickness of at least about 2 μm or more. As the mold layer MD is wafer-level coated on the buffer die wafer 10 W and first to fourth memory dies 20a to 20d with the inorganic layer OL whose stiffness is greater than that of the mold layer MD, a semiconductor package 1000 may have a top surface having an increased stiffness. In addition, as the inorganic layer OL is formed to have a thickness that is flexibly adjusted within a range of about 2 μm to about 10 μm, it may be possible to control the degree of warpage of a semiconductor package 1000. Therefore, a semiconductor package 1000 may have increased durability.

Referring to FIG. 4F, a grinding process may be performed to remove a portion of the inorganic layer OL to allow the inorganic layer OL to have a top surface OL_a that is substantially coplanar with the second top surface 2a of the fourth memory die 20d. In this case, the second top surface 2a of the second substrate 21 included in the fourth memory die 20d may be exposed. For example, the second top surface 2a of the second substrate 21 might not be covered by the inorganic layer OL. The inorganic layer OL may be formed to have a thickness of about 2 μm to about 10 μm. The inorganic layer OL may cover at least a portion of the lateral surface of the fourth memory die 20d.

Referring to FIGS. 4G and 5, the inorganic layer OL may undergo an oxygen plasma (PL) process such that a surface of the inorganic layer OL may have hydrophilic properties. The hydrogen plasma (PL) process may form a hydroxyl group on the top surface OL_a of the inorganic layer OL, and thus the top surface OL_a of the inorganic layer OL may be transformed from having hydrophobic properties to having hydrophilic properties. When the inorganic layer OL has a hydrophilic top surface OL_a, a surface energy may increase to increase an adhesive force of the inorganic layer OL.

Referring to FIG. 4H, a structure of FIG. 4G may be turned over, and a dicing tape DT may be attached to the second top surface 2a of the fourth memory die 20d and the top surface OL_a of the inorganic layer OL. The carrier adhesive layer GL and the carrier substrate CR may be removed from the buffer die wafer 10 W. The dicing tape DT may include a thermosetting resin such as an epoxy resin, a phenol resin, and a polyurethane resin or a thermoplastic resin such as an acrylic resin.

Referring to FIG. 4I, a blade dicing process may be performed to cut the inorganic layer OL, the mold layer MD, and the buffer die wafer 10 W. In the dicing process, deionized water (DI water) may be added to remove impurities produced due to friction between a blade and a semiconductor package. The hydrophilic surface of the inorganic layer OL may increase an adhesive force between the inorganic layer OL and the dicing tape DT to prevent delamination from occurring between the inorganic layer OL and the dicing tape DT. Therefore, when the dicing process is performed, it may be possible to prevent deionized water from spreading between the inorganic layer OL and the dicing tape DT and to reduce the occurrence of a water stain on a gap between the inorganic layer OL and the dicing tape DT. Manufacturing method of a semiconductor package 1000, according to embodiments of the present inventive concept, may thus have an increased yield.

The dicing tape DT may be removed to form a plurality of semiconductor packages 1000 depicted in FIG. 1B.

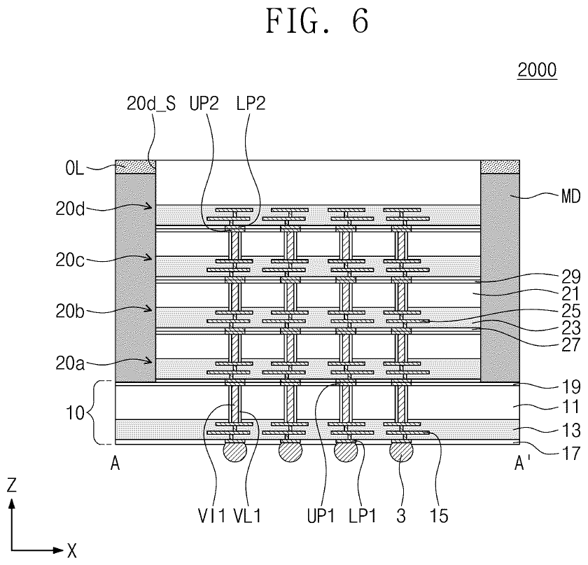

FIG. 6 illustrates a cross-sectional view taken along line A-A′ of FIG. 1A.

Referring to FIG. 6, a semiconductor package 2000 may have a structure in which a direct bonding method or a hybrid copper bonding method is used to bond the buffer die 10 and the first memory die 20a to each other and to bond the first to fourth memory dies 20a to 20d to each other in the structure of FIG. 1B. In other words, the internal connection members 30 of FIG. 1B may be omitted. The first upper conductive pads UP1 of the buffer die 10 may be correspondingly in contact with the second lower conductive pads LP2 of the first memory die 20a, and the first upper conductive pads UP1 of the buffer die 10 and the second lower conductive pads LP2 of the first memory die 20a may be formed of the same material. The second passivation layer 19 of the buffer die 10 may be in contact with the third passivation layer 27 of the first memory die 20a. In the first to fourth memory dies 20a to 20d, the second upper conductive pads UP2 and their corresponding second lower conductive pads LP2 may be in contact with each other and may be formed of the same material. In the first to fourth memory dies 20a to 20d, the third passivation layer 27 and its corresponding fourth passivation layer 29 may be in contact with each other. The semiconductor package 2000 may include neither the internal connection members 30 nor the underfill layers UF. Other configurations may be identical or similar to those discussed with reference to FIGS. 1 to 5.

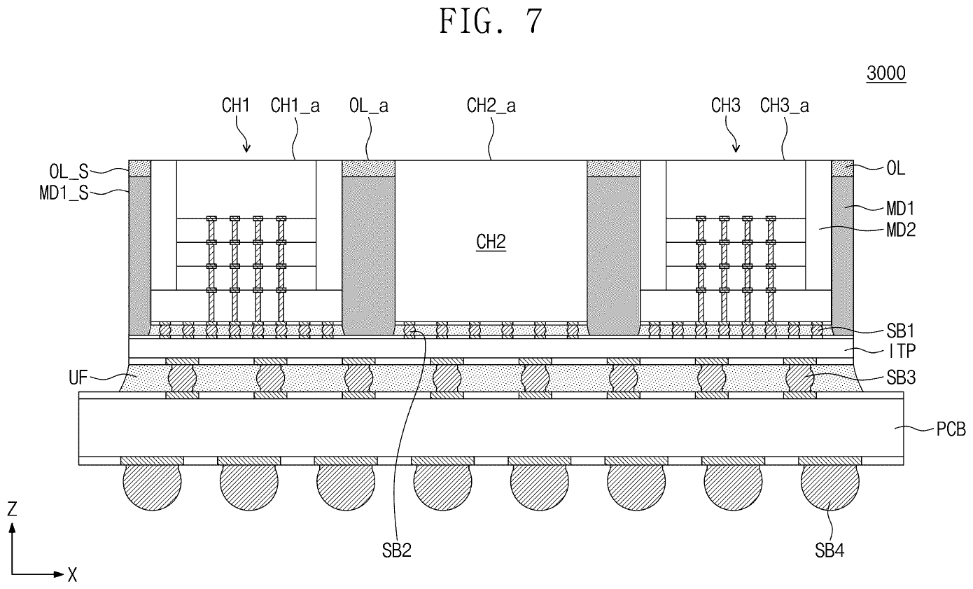

FIG. 7 is a plan view illustrating a semiconductor package according to embodiments of the present inventive concept.

Referring to FIG. 7, a semiconductor package 3000 may include a package substrate PCB, an interposer substrate ITP, first to third semiconductor chips CH1 to CH3, a first mold layer MD1, and an inorganic layer OL.

The package substrate PCB may be, for example, a double-sided or multi-layered printed circuit board. The interposer substrate ITP may include, for example, silicon. The first semiconductor chip CH1, the second semiconductor chip CH2, and the third semiconductor chip CH3 may be disposed side by side in a first direction X on the interposer substrate ITP. The interposer substrate ITP may include internal wiring lines that connect the first to third semiconductor chips CH1 to CH3 to each other.

Each of the first and third semiconductor chips CH1 and CH3 may be the same as or similar to the semiconductor package 1000 or the semiconductor package 2000 discussed with reference to FIGS. 1 to 6. Each of the first and third semiconductor chips CH1 and CH3 may include a second mold layer MD2. For example, the second semiconductor chip CH2 may be an application specific integrated circuit (ASIC) or a system-on-chip (SOC). For example, the second semiconductor chip CH2 may be called a host or an application processor (AP).

The inorganic layer OL may cover at least portions of lateral surfaces of the first to third semiconductor chips CH1 to CH3. A top surface OL_a of the inorganic layer OL may be substantially coplanar with each of top surfaces CH1_a to CH3_a of the first to third semiconductor chips CH1 to CH3. A lateral surface OL_S of the inorganic layer OL may be vertically aligned with a lateral surface MD1_S of the first mold layer MD1.

The first and third semiconductor chips CH1 and CH3 may each be connected to the interposer substrate ITP through first external connection members SB1. The second semiconductor chip CH2 may be connected to the interposer substrate ITP through second external connection members SB2. The interposer substrate ITP may be bonded to the package substrate PCB through third external connection members SB3. Fourth external connection members SB4 may be bonded to a lower portion of the package substrate PCB. The external connection members SB1 to SB4 may include at least one of, for example, copper bumps, copper pillars, and solder balls.

An underfill layer UF may be provided to fill spaces between the first semiconductor chip CH1 and the interposer substrate ITP, between the second semiconductor chip CH2 and the interposer substrate ITP, between the third semiconductor chip CH3 and the interposer substrate ITP, and between the interposer substrate ITP and the package substrate PCB. The underfill layer UF may be formed by dispensing and curing processes. The underfill layer UF may include an epoxy resin, and may protect the external connection members SB1 to SB3.

According to a semiconductor package in accordance with embodiments of the present inventive concept, a mold layer may be provided on the semiconductor package with an inorganic layer whose heat resistance is greater than that of the mold layer, and the semiconductor package may have an increased efficiency of thermal radiation. The inorganic layer may have a stiffness greater than that of the mold layer, and thus, the semiconductor package may be protected from an external impact and may be prevented from warpage.

According to a method of fabricating a semiconductor package in accordance with embodiments of the present inventive concept, an oxygen plasma process may be performed such that an inorganic layer may be formed to have a hydrophilic surface, and thus, there may be an increased adhesive force between the inorganic layer and a dicing tape. The increase in adhesive force between the inorganic layer and the dicing tape may prevent a process failure such as a delamination occurrence between the semiconductor package and the dicing tape.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package comprising:
a buffer die;
a plurality of memory dies stacked on the buffer die;
a mold layer covering a portion of a top surface of the buffer die and lateral surfaces of the plurality of memory dies; and
an inorganic layer disposed on the mold layer,
wherein the inorganic layer covers at least a portion of the lateral surface of an uppermost memory die of the plurality of memory dies,
wherein a top surface of the inorganic layer is substantially coplanar with a top surface of the uppermost memory die of the plurality of memory dies, and
wherein the inorganic layer includes oxide or nitride.

2. The semiconductor package of claim 1, wherein the memory dies include first to fourth memory dies that are sequentially stacked on each other.

3. The semiconductor package of claim 2, wherein
the buffer die includes a first through via,
wherein each of the first to third memory dies includes a second through via.

4. The semiconductor package of claim 2, further comprising internal connection members disposed between the buffer die and the first memory die and between the first to fourth memory dies.

5. The semiconductor package of claim 4, further comprising an underfill layer that fills a space between the buffer die and the first memory die and spaces between the first to fourth memory dies.

6. The semiconductor package of claim 1, wherein a thermal conductivity of the inorganic layer is greater than a thermal conductivity of the mold layer.

7. The semiconductor package of claim 1, wherein a stiffness of the inorganic layer is greater than a stiffness of the mold layer.

8. The semiconductor package of claim 1, where a lateral surface of the inorganic layer is vertically aligned with a lateral surface of the mold layer.

9. The semiconductor package of claim 1, wherein the top surface of the uppermost memory die of the plurality of memory dies is higher than a top surface of the mold layer.

10. The semiconductor package of claim 1, wherein a thickness of the inorganic layer is in a range of about 2 μm to about 10 μm.

11. The semiconductor package of claim 1, wherein the top surface of the inorganic layer is flat.

12. The semiconductor package of claim 1, wherein the inorganic layer includes SiO₂.

13. The semiconductor package of claim 1, further comprising a plurality of external connection members disposed on a lower portion of the buffer die.

14. A semiconductor package comprising:
a buffer die;
a plurality of memory dies stacked on the buffer die;
a mold layer that covers a portion of a top surface of the buffer die and lateral surfaces of the plurality of memory dies; and
an inorganic layer disposed on the mold layer,
wherein the buffer die includes:
a first through via; and
a plurality of external connection members disposed on a lower portion of the buffer die,
wherein the memory dies include first to fourth memory dies that are sequentially stacked on the buffer die,
wherein each of the first to third memory dies includes a second through via,
wherein the inorganic layer covers at least a portion of the lateral surface of the fourth memory die,
wherein a top surface of the inorganic layer and a top surface of the fourth memory die are substantially coplanar with each other,
wherein a thermal conductivity of the inorganic layer is greater than a thermal conductivity of the mold layer,
wherein a stiffness of the inorganic layer is greater than a stiffness of the mold layer,
wherein a lateral surface of the inorganic layer and a lateral surface of the mold layer are vertically aligned with each other,
wherein a thickness of the inorganic layer is in a range of about 2 μm to about 10 μm, and
wherein the inorganic layer includes SiO₂.

15. The semiconductor package of claim 14, further comprising:
a plurality of internal connection members disposed between the buffer die and the first memory die and between the first to fourth memory dies; and
an underfill layer that fills a space between the buffer die and the first memory die and spaces between the first to fourth memory dies.

16. The semiconductor package of claim 14,
wherein the buffer die further includes:
a plurality of first upper conductive pads disposed on the top surface of the buffer die; and
a plurality of first lower conductive pads disposed on a bottom surface of the buffer die,
wherein each of the first to fourth memory dies includes:
a plurality of second upper conductive pads disposed on a top surface of the each of the first to fourth memory dies; and
a plurality of second lower conductive pads disposed on a bottom surface of the each of the first to fourth memory dies,
wherein the first upper conductive pads are correspondingly in contact with the second lower conductive pads of the first memory die,
wherein the first upper conductive pads are formed of a material that is the same as a material of the second lower conductive pads of the first memory die,
wherein the second upper conductive pads and the second lower conductive pads are correspondingly in contact with each other between the first to fourth memory dies, and
wherein the second upper conductive pads are formed of a material that is the same as a material of the second lower conductive pads.

17. The semiconductor package of claim 14, wherein the top surface of the inorganic layer is flat.

18. A semiconductor package, comprising:
a package substrate;
an interposer substrate disposed on the package substrate;
a first semiconductor chip, a second semiconductor chip, and a third semiconductor chip that are disposed on the interposer substrate;
a first mold layer that covers a portion of the interposer substrate and the first, second, and third semiconductor chips; and
an inorganic layer disposed on the first mold layer,
wherein each of the first and third semiconductor chips includes:
a buffer die;
a plurality of memory dies stacked on the buffer die; and
a second mold layer that covers the buffer die and the memory dies,
wherein a top surface of the inorganic layer is substantially coplanar with a top surface of each of the first, second, and third semiconductor chips,
wherein the inorganic layer includes oxide or nitride, and
wherein a thermal conductivity of the inorganic layer is greater than a thermal conductivity of each of the first and second mold layers.

19. The semiconductor package of claim 18, wherein a lateral surface of the inorganic layer and a lateral surface of the first mold layer are vertically aligned with each other.

20. The semiconductor package of claim 18, wherein the inorganic layer covers at least portions of lateral surfaces of each of the first, second, and third semiconductor chips.
